(19) United States
(12) Patent Application Publication
(10) Pub. No.: US 2026/0065926 A1
(43) Pub. Date: Mar. 5, 2026

(54) HEAT-ASSISTED MAGNETIC RECORDING AND REPRODUCTION DEVICE AND ADJUSTMENT METHOD OF THE SAME

(71) Applicants: Kabushiki Kaisha Toshiba, Tokyo (JP); Toshiba Electronic Devices & Storage Corporation, Tokyo (JP)

(72) Inventors: Takao FURUHASHI, Kawasaki Kanagawa (JP); Kaori KIMURA, Yokohama Kanagawa (JP)

(21) Appl. No.: 19/065,455

(22) Filed: Feb. 27, 2025

(30) Foreign Application Priority Data
Aug. 28, 2024 (JP) 2024-146689

(51) Int. Cl. G11B 5/02; G11B 5/00; G11B 5/012; G11B 5/31; G11B 5/60; G11B 13/08

(52) U.S. Cl. CPC G11B 5/02; G11B 5/012; G11B 5/314; G11B 5/607; G11B 13/08; G11B 2005/0021

(57) ABSTRACT

According to one embodiment, an adjustment method of a heat-assisted magnetic recording and reproduction device including a magnetic recording head and a heat-assisted magnetic recording medium, in which write characteristics are improved in a start area of a shingled magnetic recording band and in each area storing information other than user data.

### CROSS-REFERENCE TO RELATED APPLICATIONS

This application is based upon and claims the benefit of priority from Japanese Patent Application No. 2024-146689, filed Aug. 28, 2024, the entire contents of which are incorporated herein by reference.

### FIELD

Embodiments described herein relate generally to a heat-assisted magnetic recording and reproduction device and an adjustment method of the same.

### BACKGROUND

In a heat-assisted magnetic recording head, the temperature of a magnetic disk is raised for recording by laser. It is known that, at this time, components considered to originate from a magnetic film of the magnetic disk adhere to a tip of a near-field transducer (NFT) via a lubricant and generate a buildup, due to the temperature rise.

The generation of the buildup cannot be prevented on the principle of recording. In contrast, it is known that when the lubricant-cured material adheres, the transmittance of the laser is increased and the material acts as a layer which improves a transmission efficiency of the laser.

The buildup is scraped off by wear if a flying height is lowered, or is formed again by the lubricant filling a head-media interface if the flying height is increased. For this reason, such a drawback arises that when the flying height fluctuates within a disk surface, for example, when the head moves from a track with a low fly to a track with a high fly, the write performance is degraded until the buildup is generated.

### BRIEF DESCRIPTION OF THE DRAWINGS

FIG. 1 is a diagram illustrating a configuration example of a disk drive according to a sixth embodiment.

FIG. 2 is a partially exploded perspective view showing the magnetic recording and reproduction device according to the sixth embodiment.

FIG. 3 is a side view showing a magnetic head and a suspension.

FIG. 4 is a transverse cross-sectional view showing a write head and a magnetic disk, which are parts of a magnetic disk device.

FIG. 5 is a diagram illustrating an example of a start area of an SMR band.

FIG. 6 is a flow diagram illustrating an LBA allocation method of executing a method according to a first embodiment.

FIG. 7 is a block diagram illustrating a part of a heat-assisted magnetic recording and reproduction device according to a seventh embodiment.

FIG. 8 is a flow diagram illustrating the LBA allocation method of executing a method according to a second embodiment.

FIG. 9 is a block diagram showing a part of a heat-assisted magnetic recording and reproduction device according to an eighth embodiment.

FIG. 10 is a flow diagram showing an LBA allocation method of executing a method according to a third embodiment.

FIG. 11 is a block diagram showing a part of a heat-assisted magnetic recording and reproduction device according to a ninth embodiment.

FIG. 12 is a flow diagram showing an LBA allocation method of executing a method according to a fourth embodiment.

FIG. 13 is a block diagram showing a part of a heat-assisted magnetic recording and reproduction device according to a tenth embodiment.

FIG. 14 is a flow diagram showing an LBA allocation method of executing one example of a method according to a fifth embodiment.

FIG. 15 is a flow diagram showing an LBA allocation method of executing another example of the method according to the fifth embodiment.

FIG. 16 is a diagram showing an example of each area storing information other than user data.

FIG. 17 is a diagram showing an example of each area storing information other than user data.

FIG. 18 is a block diagram showing a part of a heat-assisted magnetic recording and reproduction device according to the embodiment.

FIG. 19 is a flow diagram showing an adjustment method of a heat-assisted magnetic recording and reproduction device according to the embodiment.

### DETAILED DESCRIPTION

In general, according to one embodiment, there is provided an adjustment method of a heat-assisted magnetic recording and reproduction device comprising a heat-assisted magnetic recording head and a heat-assisted magnetic recording medium, in which write characteristics are improved in a start area of a shingled magnetic recording (SMR) band and in each area storing information other than user data. By various processes used to improve the write characteristics, this adjustment method can be divided into the first embodiment to the fifth embodiment provided below.

In an adjustment method of a heat-assisted magnetic recording and reproduction device according to the first embodiment, a bit density (bit per square inch (BPI)) is changed to a value lower than that of areas other than the start area, thereby improving the write characteristics.

In an adjustment method of a heat-assisted magnetic recording and reproduction device according to the second embodiment, a parity number is changed to be higher level than a parity number of a track error correcting code (Track ECC (error correcting code)) in areas other than the start area, thus strengthen the track ECC and increasing the parity number, thereby improving the write characteristics.

In an adjustment method of a heat-assisted magnetic recording and reproducing device according to the third embodiment, a laser current or write current is changed to a higher level than a laser current or write current in areas other than the start area, thereby improving the write characteristics.

In an adjustment method of a heat-assisted magnetic recording and reproduction device of the fourth embodiment, a TPI (tracks per inch) is lowered to a level lower than that of areas other than the start area, thereby improving the write characteristics.

In an adjustment method of a heat-assisted magnetic recording and reproducing device according to the fifth embodiment, a flying height of the heat-assisted magnetic recording head is lowered or raised, for example, gradually by each track, compared to that of areas other than the start area, thereby improving the write characteristics.

Further, there is provided a heat-assisted magnetic recording and reproducing device according to the embodiment is a device for carrying out each of the adjustment methods for the heat-assisted magnetic recording and reproducing device, which comprises a heat-assisted magnetic recording head comprising a main magnetic pole, a near-field transducer that generates near-field light, a waveguide that propagates light to the near-field transducer, and a light source that supplies light to the waveguide, a heat-assisted magnetic recording medium comprising a lubricant layer on a recording surface thereof opposing the heat-assisted magnetic recording head, a change instruction unit which instructs change of a set value of each parameter in the process of improving the write characteristics in a start area of an SMR band and in each area storing information other than user data, and a controller which controls the change of the set value of each parameter in the process for improving the write characteristics in the start area of the SMR band and in each area storing information other than user data, based on the information from the change instruction unit.

The heat-assisted magnetic recording and reproducing device according to the embodiment can be divided into the sixth embodiment to the tenth embodiment provided below, which correspond to the adjustment methods of the first embodiment to the fifth embodiment.

In the heat-assisted magnetic recording and reproducing device according to the sixth embodiment, the set value for the parameter is BPI, the change instruction unit is a BPI change instruction unit, and the controller is a format controller.

In the heat-assisted magnetic recording and reproduction device according to the seventh embodiment, the set value for the parameter is a track ECC, the change instruction unit is a track ECC change instruction unit, and the controller is a format controller.

In the heat-assisted magnetic recording and reproduction device according to the eighth embodiment, the set value for the parameter is a laser current or write current, the change instruction unit is a laser current/write current change instruction unit, and the controller is a format controller.

In the heat-assisted magnetic recording and reproduction device according to the ninth embodiment, the set value for the parameter is TPI, the change instruction unit is a TPI change instruction unit, and the controller is a servo controller.

In the heat-assisted magnetic recording and reproduction device according to the tenth embodiment, the set value for the parameter is a flying height, the change instruction unit is a flying height change instruction unit, and the controller is a flying height controller.

According to the first to tenth embodiments, it is possible to apply a correction to obtain sufficient write characteristics in advance for areas where there is a high risk of write operated in a state where a buildup is scraped, such as the start area of the SMR band and each area storing information other than user data. With this configuration, the risk which may cause read errors can be avoided. Thus, good write characteristics can be maintained for the heat-assisted magnetic recording and reproduction device.

Areas subjected to write with a low buildup height and are at risk of read errors are areas that are likely to be written at the start, and specifically they include the start area of the SMR band area, or areas that are used periodically and independently of user data within the controller firmware (FW), such as the ATI management area, media cache area, system area, and areas that measure read/write (RW) characteristics.

Note here that the system area refers to the area that stores the information necessary for controlling the magnetic recording and reproduction device. This information is separated from the data received from the host.

The area for improving the write characteristics can be an area of one track or more.

In addition to the fact that it is of a general process that the BPI is lowered for improving write characteristics, it is also possible to strengthen it by increasing the parity number of track ECC. In addition, another option can be to increase the laser current, write current, or both, while decreasing the TPI. Further, it is also possible to improve the characteristics by decreasing or increasing the flying height. Furthermore, when the flying height is increased, it is possible to guarantee build-up for areas that are not corrected by gradually increasing the flying height for each track.

### EXAMPLES

### Example 1

Embodiments will now be described with reference to the accompanying drawings.

The disclosure is merely an example and is not limited by contents described in the embodiments described below. Modification which is easily conceivable by a person of ordinary skill in the art comes within the scope of the disclosure as a matter of course. In order to make the description clearer, the sizes, shapes and the like of the respective parts may be changed and illustrated schematically in the drawings as compared with those in an accurate representation. Constituent elements corresponding to each other in a plurality of drawings are denoted by the same reference numerals and their detailed descriptions may be omitted unless necessary.

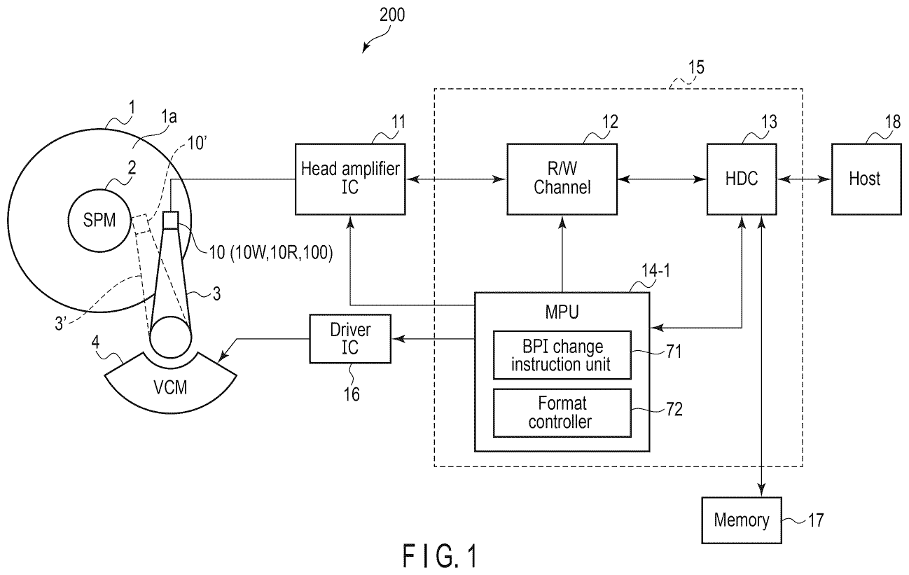

First, with reference to FIG. 1, a configuration example of a disk drive related to the sixth embodiment will be explained. Note that the configuration of the disk drive, which is a magnetic recording and reproduction device, shown in FIG. 1 is also applicable to each of the embodiments to be described later.

As shown in FIG. 1, a disk drive 200 is a magnetic disk drive of a perpendicular magnetic recording scheme, incorporating a magnetic disk 1 that is a perpendicular magnetic recording medium and a magnetic head 10 including a magnetic flux control layer to be described later.

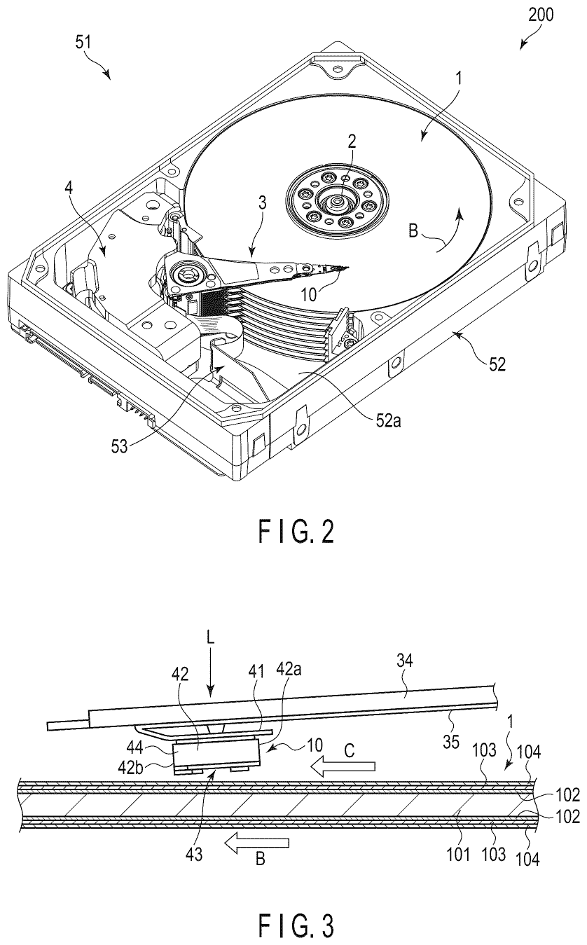

FIG. 2 is a partially exploded perspective view showing a magnetic recording and reproducing device according to the sixth embodiment.

FIG. 2 illustrates a state in which a plurality of magnetic disks 1 and a plurality of magnetic heads 10 are housed in a housing 51 in the magnetic recording and reproducing device according to the sixth embodiment, and a lid portion is omitted.

The magnetic disks 1 are fixed to a spindle motor (SPM) 2 and mounted to make rotational motion. The magnetic heads 10 are mounted on an actuator 3 and are configured to move in a radial direction on the magnetic disks 1. The actuator 3 is driven to rotate by a voice coil motor (VCM) 4. In FIG. 1, for example, it can be shown that the magnetic head 10 is sought at a first position on a recording surface 1a and that a magnetic head 10′ mounted on an actuator 3′ is sought at a second position whose radial position is different from the first position. The magnetic head 10 comprises a write head 10W, a read head 10R, and a thermal assist unit 100. The write head 10W writes data to the magnetic disk 1. The read head 10R reads data from the magnetic disk 1. The thermal assist unit 100 assists in writing data when the write head 10W writes data to the magnetic disk 1. The magnetic head 10 can include one or more magnetic heads.

Furthermore, the disk drive includes a head amplifier integrated circuit (hereinafter referred to as a head amplifier IC) 11, a read/write channel (R/W channel) 12, a hard disk controller (HDC) 13, a microprocessor (MPU) 14-1, a driver IC 16, and a memory 17. The R/W channel 12, the HDC 13, and the MPU 14-1 are incorporated into a controller 15, which consists of a single-chip integrated circuit.

The head amplifier IC 11 includes a circuit group for driving a laser diode for thermal assist, as will be described later. Further, the head amplifier IC 11 includes a driver that supplies to the recording head 10W a recording signal (write current) corresponding to the write data supplied from the R/W channel 12. In addition, the head amplifier IC 11 also includes a read amplifier that amplifies the read signal output from the reproducing head 10R and transmits the read signal to the R/W channel 12.

The R/W channel 12 is a signal processing circuit of the read/write data. The HDC 13 constitutes an interface between the disk drive and a host 18, and executes transfer control of the read/write data.

The MPU 14-1 is a main write operation controller of the disk drive and executes servo control necessary for controlling read/write operations and positioning the magnetic head 10. Further, the MPU 14-1 includes a BPI change instruction unit 71 that instructs changes to the BPI in the start area of the SMR band and in each area that stores information other than user data, and a format controller 72 that improves write characteristics by changing the BPI in the start area of the SMR band and in each area that stores information other than user data, to a value lower than that of the BPI of the area other than the start area, based on the information of the BPI change instruction unit 71.

The memory 17 includes a buffer memory composed of DRAM, a flash memory and the like.

FIG. 3 is a side view showing the magnetic head 10 and a suspension.

As shown in FIG. 3, each magnetic head 10 is constituted as a flying head, and includes a slider 42 having a shape of a substantially rectangular parallelepiped and a recording and reproducing head unit 44 provided at an outflow end (trailing end) of the slider 42. The magnetic head 10 is secured to a gimbal spring 41 provided at an end portion of a suspension 34. A head load L toward the surface of the magnetic disk 1 is applied to each magnetic head 10 by the elasticity of the suspension 34. As shown in FIG. 2, each magnetic head 10 is connected to a head amplifier IC 11 and an HDC 13 via the suspension 34 and a wiring member (flexure) 35 fixed on the arm.

Next, the structure of the magnetic disk 1 and the magnetic head 10 will be described in detail.

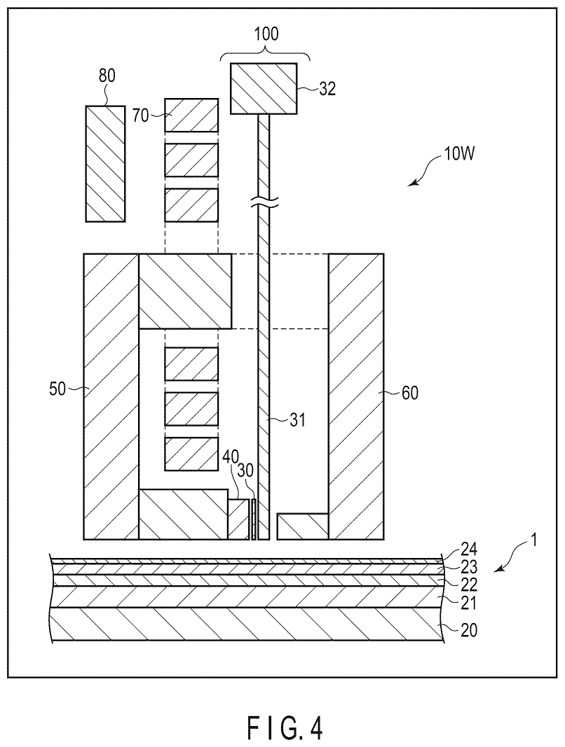

FIG. 4 is a transverse cross-sectional view showing the write head 10W and magnetic disk 1, which are parts of the magnetic disk drive.

The magnetic disk 1 includes a substrate 20, a heat sink layer 21, a crystal orientation layer 22, a perpendicular recording layer 23, and a protective film 24 having a surface coated with a lubricant to form a lubricant layer, which are stacked in order on the substrate 20. The perpendicular recording layer 23 has a large anisotropy perpendicular to the disk surface. The crystal orientation layer 22 is arranged under the perpendicular recording layer 23 to improve the orientation of that perpendicular recording layer 23. The heat sink layer 21 is arranged under the crystal orientation layer 22 to suppress the spread of the heating area. The protective film 24 is arranged on an upper part of the perpendicular recording layer 23 to protect the perpendicular recording layer 23.

The magnetic head 10 is a separated magnetic head in which the recording head 10W and the reproducing head 10R are separated, and the recording head 10W is composed of a main magnetic pole 40 formed of a high permeability material that generates a magnetic field perpendicular to the disk surface, a trailing yoke 50 magnetically bonded to the main magnetic pole that flows a magnetic flux to the main magnetic pole 40, a return shield magnetic pole 60 provided to efficiently close a magnetic path directly under the main magnetic pole, which is arranged on a leading side of the main magnetic pole 40, a coil 70 arranged to wrap around the magnetic path including the trailing yoke and the return shield magnetic pole to pass the magnetic flux to the main magnetic pole 40, a heater 80 for controlling the height of flying of the recording head, a near-field transducer 30 that generates near-field light to heat the perpendicular recording layer 23 of the magnetic disk 1 on the leading side of the main magnetic pole 40, and a waveguide 31 that propagates the light for generating the near-field light. A light source is incorporated such that a laser diode 32 is mounted on a slider of the actuator assembly 3. The near-field transducer 30 can be formed of, for example, Au, Pd, Pt, Rh, or Ir, or an alloy consisting of a combination of some of these. An insulating layer between the main magnetic pole and the near-field transducer can be formed of, for example, an oxide of SiO₂, Al₂O₃, or the like.

The write current is a current that can be used for data recording, which is, for example, the current applied to the magnetic coil of the recording head at the time of data recording. Further, a current that makes the light source to emit light is referred to as a light source drive current. As the light source, for example, a laser light source can be used.

Recording methods for heat-assisted magnetic recording that can be used in the magnetic disk device 200 include so-called Conventional Magnetic Recording (CMR) for writing data in tracks at intervals in the radial direction and performing recording such that adjacent tracks do not overlap, so-called Shingled Magnetic Recording (SMR) including tracks stacked in order in the radial direction and recording over parts of the adjacent tracks, or so-called Interlaced Magnetic Recording (IMR) including a bottom track and a top track in which adjacent tracks are stacked alternately and, after recording on the bottom track, recording while stacking the bottom track on the interlaced top track, or a combination of these methods.

Further, when a change in BPI, a change in track ECC, a change in laser current or write current, a change in TPI, a change in the flying height or the like is detected, it can be notified to the host 18. At this time, the host 18 can be notified using the self-monitoring analysis and reporting technology (SMART) function.

The first embodiment provides an adjustment method of a heat-assisted magnetic recording and reproduction device, which is an adjustment method of a heat-assisted magnetic recording and reproduction device comprising a heat-assisted magnetic recording head and a heat-assisted magnetic recording medium, in which the bit densities of the start area of the SMR band and each area storing information other than user data are changed to a lower bit density than those of the areas other than the start area, and thus the write characteristics are improved.

The adjustment method of the heat-assisted magnetic recording and reproduction device of the first embodiment can be applied to the heat-assisted magnetic recording and reproduction device of the sixth embodiment, and the heat-assisted magnetic recording and reproduction device of the sixth embodiment comprises a heat-assisted magnetic recording head comprising a main magnetic pole, a near-field transducer that generates near-field light, a waveguide that propagates light to the near-field transducer, and a light source that supplies light to the waveguide, and a heat-assisted magnetic recording medium comprising a lubricant layer on a recording surface thereof opposing the heat-assisted magnetic recording head, and a bit density change instruction unit that instructs a change in the bit density in the start area of the SMR band and in each area storing information other than user data, and a format controller that improves the write characteristics by changing the bit density to a lower value than the bit density of the area other than the above-described start area in the start area of the shingled magnetic recording (SMR) band and in each area that stores information other than user data, based on the information of the bit density change instruction unit.

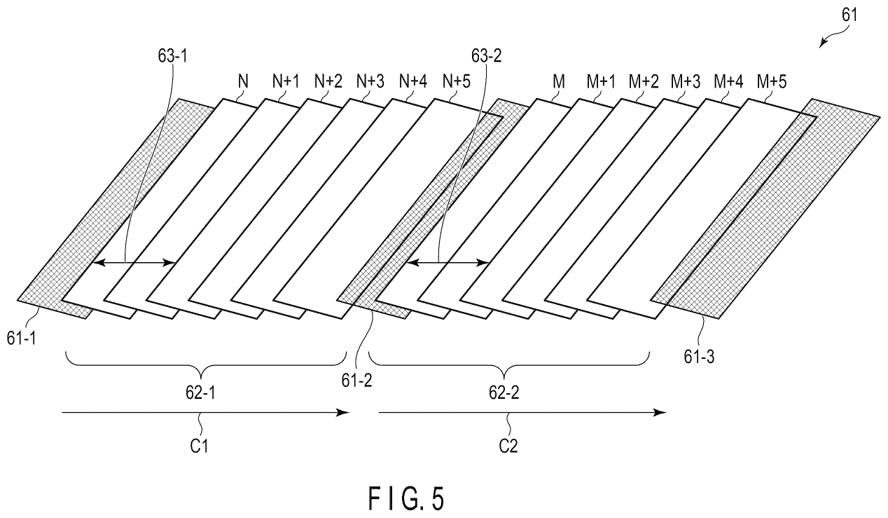

FIG. 5 is a diagram illustrating an example of the start area of the SMR band.

Here, as shown in the figure, between one band 62-1 of the shingled magnetic recording and another band 62-2a adjacent thereto, a guard band 61-2 is provided. In the band 62-1, tracks N, N+1, N+2, N+3, N+4, and N+5, which are stacked in a shingled manner in a write direction indicated by an arrow C1, are provided. In the guard band 61-2 and a band 62-2, there are tracks M, M+1, M+2, M+3, M+4, and M+5, which are stacked in a shingled manner in the write direction indicated by an arrow C2 provided. The guard band 61-2 is located slightly distant away from the track N+5 and track M on both sides thereof, and they are not stacked in a shingled manner. On an opposite side to the guard band 61-2, a guard band 61-1 is provided via the band 62-1 of shingled magnetic recording, and on an opposite side to the guard band 61-2, a guard band 61-3 is provided via the band 62-2 of shingled magnetic recording. Thus, each one is slightly distant away from the tracks on both sides and they are not stacked in a shingled manner. The area indicated by an arrow 63-1 indicates the start area of the band 62-1, and the area indicated by an arrow 63-2 indicates the start area of the band 62-2.

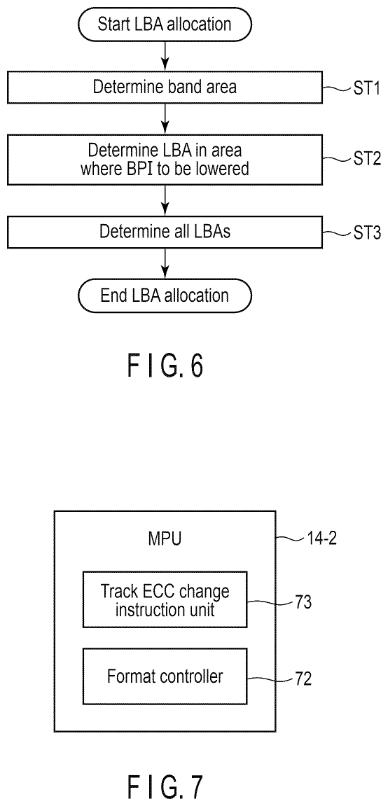

FIG. 6 is a flow diagram showing a logical block address (LBA) allocation process for executing the adjustment method using the magnetic recording and reproduction device of the first embodiment.

Example 1 illustrates an example of a method of adjusting the magnetic recording and reproduction device of the first embodiment, in which the write characteristics are improved by changing the BPI to a lower BPI than the BPI of the area other than the start area in the start area of the SMR band.

A magnetic disk with a capacity determined on the premise of lowering the BPI is prepared, and the allocation of LBA is started. First, the band area to be used is determined, for example, as the band 62-1 and band 62-2 in FIG. 5 (ST1). Next, the LBAs for the areas where the BPI is to be lowered, for example, the start areas 63-1 and 63-2, are determined (ST2). After that, the overall LBAs are determined (ST3).

Subsequently, the change in BPI is instructed by the BPI change instruction unit 71. Further, the BPIs of the start area 63-1 and 63-2 are changed by the format controller 72 to be lowered by about 10% compared to the BPIs of the areas other than the start areas 63-1 and 63-2 to improve the write characteristics.

According to the embodiment, in the area where there is a risk of read errors as being written with a low build-up height, such a correction to obtain sufficient write characteristics can be applied in advance. With this configuration, it is possible to avoid the risk which may create read errors and maintain good write characteristics in the heat-assisted magnetic recording and reproduction device.

An example of the magnetic disk 1 contained in the magnetic recording and reproduction device 200 of the embodiment can be a perpendicular magnetic recording medium. An example of the perpendicular magnetic recording medium can be a magnetic recording layer of a granular structure, for example. The magnetic recording layer with a granular structure contains magnetic particles having an L1₀ structure as a magnetic material. Examples of the magnetic particle having the L1₀ structure are FePt alloy particles and CoPt alloy particles. As to the grain boundary, C, BN, and oxides containing SiO₂ can be included as grain boundary materials. It is considered that the buildup is a hardened substance that is formed when siloxane gas floating in the magnetic recording and reproduction device or components originated from the magnetic recording layer, such as SiO₂ contained in the grain boundary, adheres to the tip of the NFT via a lubricant. Further, a protective layer can be formed on the magnetic recording layer. For example, carbon (C), diamond-like carbon, SiO₂, or ZrO₂ can be used as the protective layer. For example, perfluoropolyether, fluoroalcohol, or fluorinated carboxylic acid can be used as the lubricant to be applied to the recording surface of the magnetic disk.

### Example 2

Example 2 shows an example of a method of adjusting a heat-assisted magnetic recording and reproduction device according to the second embodiment.

The method of adjusting the heat-assisted magnetic recording and reproduction device according to the second embodiment is a method of adjusting a heat-assisted magnetic recording and reproduction device comprising a heat-assisted magnetic recording head and a heat-assisted magnetic recording medium, in which the parity number of the track ECC is changed to a higher value in the start area of the SMR band and each area storing information other than user data, than those of the areas other than the above-described start area so as to strengthen the track ECC, and thus the write characteristics are improved by increasing the parity number.

For the adjustment method of the heat-assisted magnetic recording and reproduction device of the second embodiment, a heat-assisted magnetic recording and reproduction device shown in the seventh embodiment can be used.

The heat-assisted magnetic recording and reproduction device of the seventh embodiment comprises a heat-assisted magnetic recording head comprising a main magnetic pole, a near-field light transducer that generates near-field light, a waveguide that propagates light to the near-field transducer, and a light source that supplies light to the waveguide, a heat-assisted magnetic recording medium comprising a lubricant layer on the recording surface thereof opposing the heat-assisted magnetic recording head, a track error correction code change instruction unit that instructs the change of a track error correction code (increasing the parity number) in the start area of the shingled magnetic recording band and in each area storing information other than user data, and a format controller that improves the write characteristics by changing the parity number to a higher value in the start area of the shingled magnetic recording band and in each area storing information other than user data, than the parity number of the track error correction code in the areas other than the above-described start area, based on the information from the track error correction code change instruction unit and thereby strengthen the track error correction code (increasing the parity number).

The example of the heat-assisted magnetic recording and reproduction device according to the seventh embodiment has a configuration similar to that shown in FIG. 1, except that an MPU 14-2 which contains the change instruction unit 73 and the format controller 72 shown in FIG. 7 is provided in place of MPU 14-1.

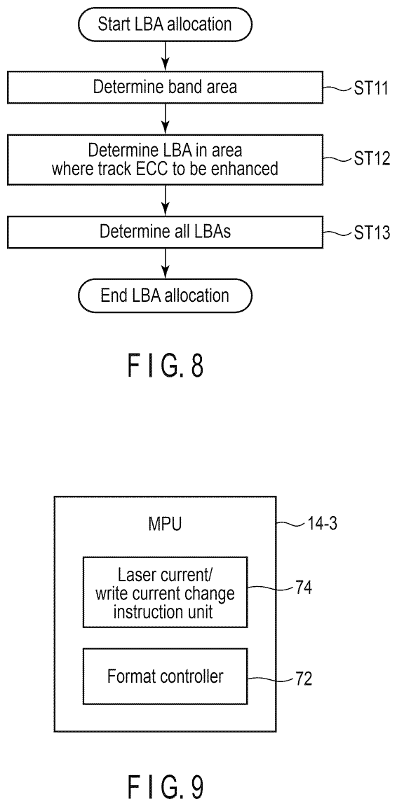

FIG. 8 is a flow diagram showing a logical block address (LBA) allocation process for executing the adjustment method of the magnetic recording and reproduction device of the second embodiment.

A magnetic disk with a capacity determined on the premise of strengthening the BPI is prepared in advance, and the allocation of LBA is started. First, the band area to be used is determined, for example, as the band 62-1 and band 62-2 in FIG. 5 (ST11). Next, the LBAs for the areas where the track ECC is to be lowered, for example, the start areas 63-1 and 63-2, are determined (ST12). After that, the overall LBAs are determined (ST13).

Next, the change in track ECC is instructed by the track ECC change instruction unit 73. Further, the track ECC of the start areas 63-1 and 63-2 is changed to twice the amount of the track ECC of the area other than the start areas 63-1 and 63-2 by the format controller 72 so as to strengthen it and improve the write characteristics.

According to the embodiment, in an area where there is a risk which may create read errors due to the write at a low build-up height, a correction which can ensure sufficient write characteristics in advance can be applied. With this configuration, it is possible to avoid the risk which may create read errors and maintain good write characteristics for the heat-assisted magnetic recording and reproduction device.

### Example 3

Example 3 illustrates an example of a method of adjusting a heat-assisted magnetic recording and reproduction device according to the third embodiment.

The adjustment method of the heat-assisted magnetic recording and reproduction device of the third embodiment is an adjustment method of the heat-assisted magnetic recording and reproduction device comprising a heat-assisted magnetic recording head and a heat-assisted magnetic recording medium, in which the write characteristics are improved by changing the laser current or write current to a higher level in the start area of the SMR band and in each area storing information other than user data than the laser current or write current of the areas other than the above-described start area.

To the adjustment method of the heat-assisted magnetic recording and reproduction device of the third embodiment, a heat-assisted magnetic recording and reproduction device of the eighth embodiment can be used.

The heat-assisted magnetic recording and reproduction device of the eighth embodiment is a heat-assisted magnetic recording and reproduction device comprising a heat-assisted magnetic recording head comprising a main magnetic pole, a near-field transducer that generates near-field light, a waveguide that propagates light to the near-field transducer, and a light source that supplies light to the waveguide, a heat-assisted magnetic recording medium comprising a lubricant layer on a recording surface thereof opposing the heat-assisted magnetic recording head, and a laser current/write current change instruction unit that instructs a change in laser current or write current in the start area of the shingled magnetic recording band and in each area storing information other than user data, and a format controller that improves the write characteristics by increasing the laser current or write current to a higher level in the start area of the shingled magnetic recording band and in each area storing information other than user data, than those of the areas other than the above-described start area, based on the information from the laser current/write current change instruction unit.

The example of the heat-assisted magnetic recording and reproduction device according to the eighth embodiment has a configuration similar to that shown in FIG. 1, except that an MPU 14-3 which includes the laser current/write current change instruction unit 74 and the format controller 72 shown in FIG. 9 is provided in place of the MPU 14-1.

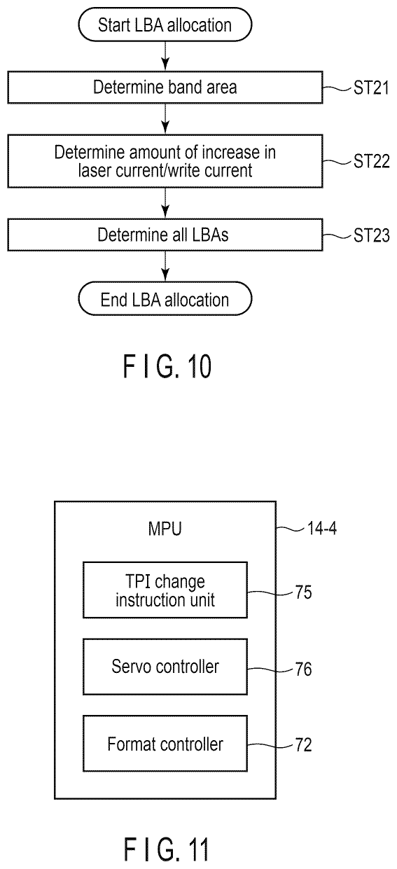

FIG. 10 is a flow diagram showing a logical block address (LBA) assignment process for executing an adjustment method of a magnetic recording and reproduction device according to the third embodiment.

A magnetic disk is prepared, and the allocation of LBA is started. First, the band area to be used is determined, for example, as the band 62-1 and band 62-2 in FIG. 5 (ST21). Next, the LBAs for the areas where the laser current or write current is to be increased, for example, the start areas 63-1 and 63-2, are determined (ST22). After that, the overall LBAs are determined (ST23).

Subsequently, the change in laser current or write current is instructed by the laser current/write current change instruction unit 74. Further, the laser current or write current of the start areas 63-1 and 63-2 is changed to be 5% higher than the laser current or write current of the areas other than the start area 63-1 and 63-2 by the format controller 72 so as to improve the write characteristics.

According to the embodiment, in an area where there is a risk which may cause read errors due to the write is done at a low buildup height, such a correction to obtain sufficient write characteristics can be applied in advance. With this configuration, it is possible to avoid the risk which may cause read errors and maintain good write characteristics of the heat-assisted magnetic recording and reproducing device.

### Example 4

Example 4 shows an example of a method of adjusting a heat-assisted magnetic recording and reproducing device according to the fourth embodiment.

The adjustment method of the heat-assisted magnetic recording and reproduction device of the fourth embodiment is an adjustment method of the heat-assisted magnetic recording and reproduction device comprising a heat-assisted magnetic recording head and heat-assisted magnetic recording medium, in which the write characteristics are improved by lowering the TPI of the areas other than the above-described start area to a lower level in the start area of the SMR band and in each area storing information other than user data.

To the adjustment method of the heat-assisted magnetic recording and reproducing device of the fourth embodiment, a heat-assisted magnetic recording and reproducing device according to the ninth embodiment can be used.

The heat-assisted magnetic recording and reproduction device of the ninth embodiment comprises a heat-assisted magnetic recording head comprising a main magnetic pole, a near-field transducer that generates near-field light, a waveguide that propagates light to the near-field transducer, and a light source that supplies light to the waveguide, a heat-assisted magnetic recording medium comprising a lubricant layer on a recording surface thereof that opposes the heat-assisted magnetic recording head magnetic recording medium, and a track density change instruction unit that instructs changes in track density (TPI) in the start area of the shingled magnetic recording band and in each area storing information other than user data, and a servo controller that improves write characteristics by reducing the track density to a lower level in the start area of the shingled magnetic recording band and in each area storing information other than user data than those of the areas other than the above-described start area, based on the information from the track density change instruction unit.

The example of the heat-assisted magnetic recording and reproduction device according to the ninth embodiment has a configuration similar to that shown in FIG. 1, except that an MPU 14-4 which includes the TPI change instruction unit 75, servo controller 76, and the format controller 72 shown in FIG. 11 is provided in place of the MPU 14-1.

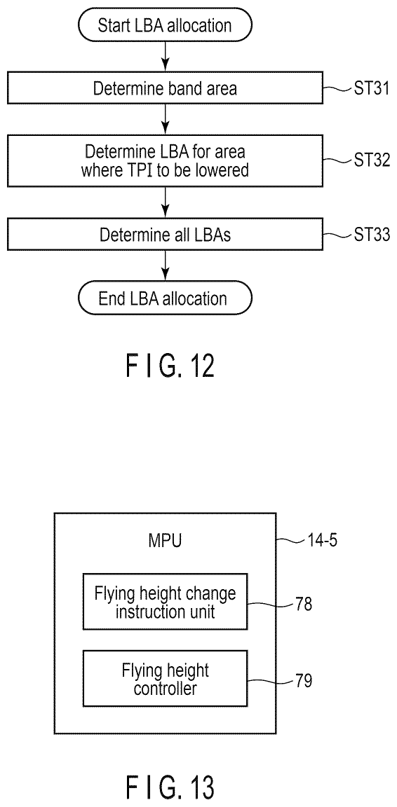

FIG. 12 is a flow diagram showing the logical block address (LBA) allocation process for executing the adjustment method of the magnetic recording and reproduction device of the fourth embodiment.

A magnetic disk is prepared, and the allocation of LBA is started. First, the band area to be used is determined, for example, as the band 62-1 and band 62-2 in FIG. 5 (ST31). Next, the LBAs for the areas where the TPI is to be lowered, for example, the start areas 63-1 and 63-2, are determined (ST32). After that, the overall LBAs are determined (ST33).

Subsequently, a change in the TPI to a lower level is instructed by the TPI change instruction unit 75. Further, the TPIs of the start areas 63-1 and 63-2 are changed to be 2% lower than the TPIs of the areas other than the start area 63-1 and 63-2 by the servo controller 76 and the format controller 72, thereby improving the write characteristics.

According to the embodiment, in areas where there is a risk which may cause read errors due to a write at a low buildup height, such a correction to obtain sufficient write characteristics can be applied in advance. With this configuration, it is possible to avoid the risk that may cause read errors and maintain good write characteristics of the heat-assisted magnetic recording and reproduction device.

### Example 5

Example 5 shows an example of a method of adjusting a heat-assisted magnetic recording and reproduction device according to the fifth embodiment.

The adjustment method of the heat-assisted magnetic recording and reproduction device of the fifth embodiment is an adjustment method of the heat-assisted magnetic recording and reproduction device comprising a heat-assisted magnetic recording head and a heat-assisted magnetic recording medium, in which the flying height of the heat-assisted magnetic recording head is lowered in the start area of the SMR band area and in each area that stores information other than user data, or the flying height is raised, for example, gradually for each track, to improve the write characteristics.

To the adjustment method of the heat-assisted magnetic recording and reproduction device of the fifth embodiment, the heat-assisted magnetic recording and reproduction device of the tenth embodiment can be used.

The heat-assisted magnetic recording and reproduction device of the tenth embodiment comprises a heat-assisted magnetic recording head comprising a main magnetic pole, a near-field transducer that generates near-field light, a waveguide that propagates light to the near-field transducer, and a light source that supplies light to the waveguide, a heat-assisted magnetic recording medium comprising a lubricant layer on a recording surface thereof, which opposes the heat-assisted magnetic recording head, a flying height change instruction unit that instructs changes in the flying height in the start area of the shingled magnetic recording band and in each area storing information other than user data, and a flying height controller that improves write characteristics by lowering the flying height (or gradually raising it for each track) in the start area of the shingled magnetic recording band and in each area storing information other than user data, as compared to those of the areas other than the above-described start area, based on information from the flying height change instruction unit.

The example of the heat-assisted magnetic recording and reproduction device according to the tenth embodiment has a configuration similar to that shown in FIG. 1, except that an MPU 14-5 which includes the flying height change instruction unit 78 and the flying height controller 79 shown in FIG. 13 is provided in place of the MPU 14-1.

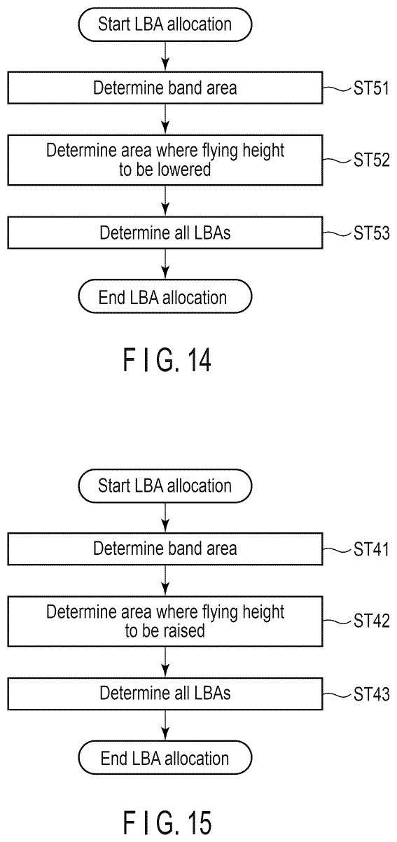

FIG. 14 is a flow diagram showing the logical block address (LBA) allocation process for executing an example of the adjustment method of the magnetic recording and reproduction device of the fifth embodiment.

A magnetic disk is prepared, and the allocation of LBA is started. First, the band area to be used is determined, for example, as the band 62-1 and band 62-2 in FIG. 5 (ST51). Next, the LBAs for the areas where the flying height is to be lowered, for example, the start areas 63-1 and 63-2, are determined (ST52). After that, the overall LBAs are determined (ST53).

Subsequently, the change to lower the flying height is instructed by the flying height change instruction unit 78. Further, the flying height in the start area 63-1 and 63-2 is changed to be 10% lower than the flying height in the areas other than the start areas 63-1 and 63-2, so as to improve the write characteristics.

In addition, such a change instruction can be made to lower the flying height once and then gradually raise one track at a time, by the flying height change instruction unit 78. Furthermore, by using the flying height controller 79, the flying height of the start area 63-1 and 63-2 can be lowered to a level lower than the flying height of the areas other than the start area 63-1 and 63-2 once and then gradually raised by one track at a time so as to improve the write characteristics and also guarantee the buildup for the areas that are not corrected.

FIG. 15 is a flow diagram showing the logical block address (LBA) assignment process for executing another example of the adjustment method of the magnetic recording and reproduction device of the fifth embodiment.

A magnetic disk is prepared, and the allocation of LBA is started. First, the band area to be used is determined, for example, as the band 62-1 and band 62-2 in FIG. 5 (ST41). Next, the LBAs for the areas where the flying height is to be raised, for example, the start areas 63-1 and 63-2, are determined (ST42). After that, the overall LBAs are determined (ST43).

Subsequently, the change to lower the flying height is instructed by the flying height change instruction unit 78. Further, the flying height in the start area 63-1 and 63-2 is changed to be about 10% higher than the flying height in the areas other than the start areas 63-1 and 63-2 by the flying height controller 79, so as to improve the write characteristics.

Subsequently, the change to increase the flying height is instructed by the flying height change instruction unit 78. Further, the flying height in the start area 63-1 and 63-2 is changed to be about 10% higher than the flying height in areas other than the start area 63-1 and 63-2, by the flying height controller 79, so as to improve the write characteristics.

According to the embodiment, in an area where there is a risk which may cause read errors due to a write at a low buildup height, such a correction to obtain sufficient write characteristics can be applied in advance. With this configuration, it is possible to avoid the risk which may cause read errors and maintain good write characteristics of the heat-assisted magnetic recording and reproduction device.

In Examples 1 to 5, such cases of improving write characteristics in the start area of the SMR band are explained, but write characteristics are also improved in each area that stores information other than user data.

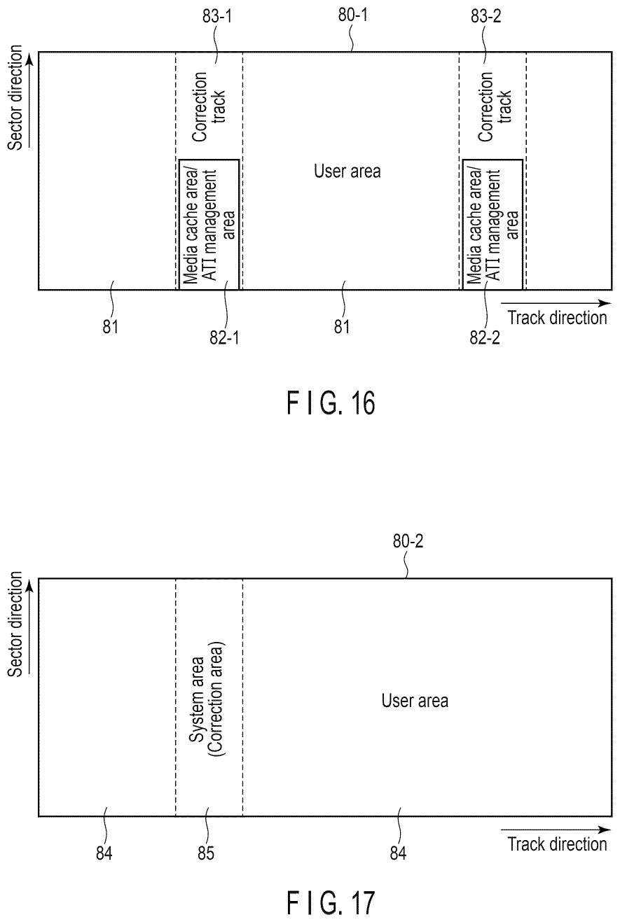

FIGS. 16 and 17 show examples of the areas that store information other than user data.

As shown in FIG. 16, an ATI management area and a media cache area can be provided in a part of a correction track 83-1 located between, for example, a user area 81 and another user area 81 adjacent thereto.

Further, as shown in FIG. 17, the system area can be provided in a correction area 83-1 located between, for example, a user area 84 and another user area 84 adjacent thereto.

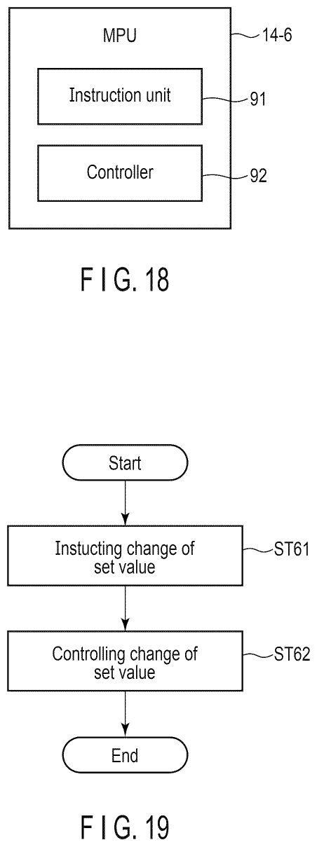

Note that the heat-assisted magnetic recording and reproduction device according to the embodiment can have a configuration similar to that shown in FIG. 1, except for an MPU 14-6 is provided in place of the MPU 14-1. The MPU 14-6 includes the instruction unit 91 and the controller 92 shown in FIG. 18.

Additionally, the adjustment method of a heat-assisted magnetic recording and reproduction device according to the embodiment comprises improving write characteristics in a start area of a shingled magnetic recording band and in each area storing information other than user data. As shown in FIG. 19, the improving write characteristics, can comprise instructing change of a set value of each parameter in the process of improving the write characteristics in a start area of a shingled magnetic recording band and in each area storing information other than user data by the change instruction unit 91 (ST61), and controlling the change of the set value by the controller 92, based on the information from the change instruction unit (ST62).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An adjustment method of a heat-assisted magnetic recording and reproduction device comprising a magnetic recording head and a heat-assisted magnetic recording medium, the method comprising:
improving write characteristics in a start area of a shingled magnetic recording band and in each area storing information other than user data.

2. The adjustment method of claim 1, wherein
the improving write characteristics comprises
changing a bit density in the start area of the shingled magnetic recording band and in each area storing information other than user data to a lower level than a bit density of areas other than the start area.

3. The adjustment method of claim 1, wherein
the improving write characteristics comprises
changing a parity number of a track error correction code in the start area of the shingled magnetic recording band and in each area storing information other than user data to a higher value than a parity number of a track error correction code in areas other than the start area, to strengthening the track error correction code.

4. The adjustment method of claim 1, wherein
the improving write characteristics comprises
changing a laser current or write current in the start area of the shingled magnetic recording band and in each area storing information other than user data to a higher level than a laser current or write current in areas other than the start area.

5. The adjustment method of claim 1, wherein
the improving write characteristics comprises
lowering a track density in the start area of the shingled magnetic recording band and in each area storing information other than user data, to a lower level than a track density in areas other than the start area.

6. The adjustment method of claim 1, wherein
the improving write characteristics comprises
lowering or raising a flying height of the heat-assisted magnetic recording head in the start area of the shingled magnetic recording band and in each area storing information other than user data, compared to the flying height of the heat-assisted magnetic recording head in areas other than the start area.

7. A heat-assisted magnetic recording and reproduction device comprising:
a heat-assisted magnetic recording head comprising a main magnetic pole, a near-field transducer that generates near-field light, a waveguide that propagates light to the near-field transducer, and a light source that supplies light to the waveguide;
a heat-assisted magnetic recording medium comprising a lubricant layer on a recording surface thereof opposing the heat-assisted magnetic recording head;
a change instruction unit which instructs change of a set value of each parameter in the process of improving write characteristics in a start area of a shingled magnetic recording band and in each area storing information other than user data; and
a controller which controls the change of the set value, based on information from the instruction unit, to improve write characteristics.

8. The heat-assisted magnetic recording and reproduction device of claim 7, wherein
the set value for the parameter is a bit density,
the change instruction unit is a bit density change instruction unit which instructs a change in bit density in the start area of the shingled magnetic recording band and in each area storing information other than user data, and
the controller is a format controller which changes the bit density in the start area of the shingled magnetic recording band and in each area storing information other than user data to a lower level than a bit density in areas other than the start area, based on information from the bit density change instruction unit, to improve write characteristics.

9. The heat-assisted magnetic recording and reproduction device of claim 7, wherein
the set value for the parameter is a track error correction code,
the change instruction unit is a track error correction code change instruction unit which instructs change of the track error correction code in the start area of the shingled magnetic recording band and in each area storing information other than user data, and
the controller is a format controller which changes a parity number of a track error correction code in the start area of the shingled magnetic recording band and in each area storing information other than user data to a higher parity number than a parity number of a track error correction code in areas other than the start area, based on information from the track error correction code change instruction unit, to improve write characteristics.

10. The heat-assisted magnetic recording and reproduction device of claim 7, wherein
the set value for the parameter is a laser current or a write current,
the change instruction unit is a laser current/write current change instruction unit which instructs change of the laser current or write current in the start area of a shingled magnetic recording band and in each area storing information other than user data, and
the controller is a format controller which increases the laser current or write current in the start area of the shingled magnetic recording band and in each area storing information other than user data, to a level higher than a laser current or write current in areas other than the start area, based on information from the laser current/write current change instruction unit, to improve write characteristics.

11. The heat-assisted magnetic recording and reproduction device of claim 7, wherein
the set value for the parameter is a track density,
the change instruction unit is a track density change instruction unit which instructs change in track density in the start area of the shingled magnetic recording band and in each area storing information other than user data and,
the controller is a servo controller which lowers the track density to a lower level than a track density in areas other the start area, based on information from the track density change instruction unit, to improve write characteristics.

12. The heat-assisted magnetic recording and reproduction device of claim 7, wherein
the set value for the parameter is a flying height,
the change instruction unit is a flying height change instruction unit which instructs change in flying height in the start area of the shingled magnetic recording band and in each area storing information other than user data, and
the controller is a flying height controller which lowers a flying height in the start area of the shingled magnetic recording band and in each area storing information other than user data to a lower level than the flying height in areas other than the start area, based on information from the flying height change instruction unit, to improve write characteristics.
